(19) United States
(12) Patent Application Publication
(10) Pub. No.: US 2010/0220262 A1
(43) Pub. Date: Sep. 2, 2010

(54) LINEARLY POLARIZED BACKLIGHT SOURCE IN CONJUNCTION WITH POLARIZED PHOSPHOR EMISSION SCREENS FOR USE IN LIQUID CRYSTAL DISPLAYS

(75) Inventors: Natalie Fellows DeMille, Carlsbad, CA (US); Steven P. DenBaars, Goleta, CA (US); Shuji Nakamura, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 12/536,400

(22) Filed: Aug. 5, 2009

Related U.S. Application Data
(60) Provisional application No. 61/086,431, filed on Aug. 5, 2008.

(51) Int. Cl. G02F 1/1335; H01L 33/44; C09K 11/80

(52) U.S. Cl. 349/64; 438/30; 252/301.4 R; 257/E33.061

(57) ABSTRACT

A device for displaying images positions a luminescent material between a light source and a liquid crystal display (LCD). The light source, which comprises one or more nonpolar or semipolar III-nitride based light emitting diodes (LEDs), emits a primary light having a specified polarization direction and comprising one or more first wavelengths. This primary light emitted by the light source is a linearly polarized light that eliminates any need for a polarizer. The luminescent material, which comprises one or more phosphors, is optically pumped by the primary light and emits a secondary light having the polarization direction of the primary light, wherein the secondary light is comprised one or more second wavelengths that are different from the first wavelength. This secondary light emitted by the luminescent material is a colored light that eliminates any need for a color filter. The LCD receives the secondary light and displays one or more images in response thereto.

### CROSS REFERENCE TO RELATED APPLICATIONS

This application claims the benefit under 35 U.S.C. Section 119(e) of co-pending and commonly-assigned:

U.S. Provisional Application Ser. No. 61/086,431 filed on Aug. 5, 2008, by Natalie N. Fellows, Steven P. DenBaars, and Shuji Nakamura, entitled “LINEARLY POLARIZED BACKLIGHT SOURCE IN CONJUNCTION WITH POLARIZED PHOSPHOR EMISSION SCREENS FOR USE IN LIQUID CRYSTAL DISPLAYS,” attorney's docket number 30794.282-US-P1 (2008-802),

which application is incorporated by reference herein.

This application is related to the following co-pending and commonly-assigned U.S. patent applications:

U.S. Utility application Ser. No. 12/272,588, filed on Nov. 17, 2008, by Hisashi Masui, Shuji Nakamura and Steven P. DenBaars, entitled “PACKAGING TECHNIQUE FOR THE FABRICATION OF POLARIZED LIGHT EMITTING DIODES,” attorneys' docket number 30794.139-US-U1 (2005-614-2), which application is a continuation of and claims the benefit under 35 U.S.C. Section 120 of U.S. Utility application Ser. No. 11/472,186, filed on Jun. 21, 2006, by Hisashi Masui, Shuji Nakamura and Steven P. DenBaars, entitled “PACKAGING TECHNIQUE FOR THE FABRICATION OF POLARIZED LIGHT EMITTING DIODES,” attorneys' docket number 30794.139-US-U1 (2005-614-2), which application claims the benefit under 35 U.S.C. Section 119(e) of U.S. Provisional Application Ser. No. 60/692,514, filed on Jun. 21, 2005, by Hisashi Masui, Shuji Nakamura and Steven P. DenBaars, entitled “PACKAGING TECHNIQUE FOR THE FABRICATION OF POLARIZED LIGHT EMITTING DIODES,” attorneys' docket number 30794.139-US-P1 (2005-614-1);

U.S. Utility application Ser. No. 12/364,258, filed on Feb. 2, 2009, by Hisashi Masui, Hisashi Yamada, Kenji Iso, James S. Speck, Shuji Nakamura, and Steven P. DenBaars, entitled “ENHANCEMENT OF OPTICAL POLARIZATION OF NITRIDE LIGHT-EMITTING DIODES BY INCREASED INDIUM INCORPORATION,” attorney's docket number 30794.259-US-U1 (2008-323), which application claims the benefit under 35 U.S.C. Section 119(e) of U.S. Provisional Application Ser. No. 61/025,592, filed on Feb. 1, 2008, by Hisashi Masui, Hisashi Yamada, Kenji Iso, James S. Speck, Shuji Nakamura, and Steven P. DenBaars, entitled “ENHANCEMENT OF OPTICAL POLARIZATION OF NITRIDE LIGHT-EMITTING DIODES BY INCREASED INDIUM INCORPORATION,” attorney's docket number 30794.259-US-P1 (2008-323);

U.S. Utility application Ser. No. 12/364,272, filed on Feb. 2, 2009, by Hisashi Masui, Hisashi Yamada, Kenji Iso, Asako Hirai, Makoto Saito, James S. Speck, Shuji Nakamura, and Steven P. DenBaars, entitled “ENHANCEMENT OF OPTICAL POLARIZATION OF NITRIDE LIGHT-EMITTING DIODES BY WAFER OFF-AXIS CUT,” attorney's docket number 30794.260-US-U1 (2008-361), which application claims the benefit under 35 U.S.C. Section 119(e) of U.S. Provisional Application Ser. No. 61/025,600, filed on Feb. 1, 2008, by Hisashi Masui, Hisashi Yamada, Kenji Iso, Asako Hirai, Makoto Saito, James S. Speck, Shuji Nakamura, and Steven P. DenBaars, entitled “ENHANCEMENT OF OPTICAL POLARIZATION OF NITRIDE LIGHT-EMITTING DIODES BY WAFER OFF-AXIS CUT,” attorney's docket number 30794.260-US-P1 (2008-361);

U.S. Utility patent application Ser. No. 12/419,119, filed on Apr. 6, 2009, by Hitoshi Sato, Hirohiko Hirasawa, Roy B. Chung, Steven P. DenBaars, James S. Speck and Shuji Nakamura, entitled “METHOD FOR FABRICATION OF SEMIPOLAR (Al,In,Ga,B)N BASED LIGHT EMITTING DIODES,” attorneys' docket number 30794.264-US-U1 (2008-415); which application claims the benefit under 35 U.S.C. Section 119(e) of U.S. Provisional Patent Application Ser. No. 61/042,644, filed on Apr. 4, 2008, by Hitoshi Sato, Hirohiko Hirasawa, Roy B. Chung, Steven P. DenBaars, James S. Speck and Shuji Nakamura, entitled “METHOD FOR FABRICATION OF SEMIPOLAR (Al,In,Ga,B)N BASED LIGHT EMITTING DIODES,” attorneys' docket number 30794.264-US-P1 (2008-415-1);

U.S. Provisional Application Ser. No. 61/051,279, filed on May 7, 2008, by Hisashi Masui, Natalie N. Fellows, Shuji Nakamura and Steven P. DenBaars, entitled “UTILIZATION OF SIDEWALL EMISSION FROM LIGHT-EMITTING DIODES AS POLARIZED LIGHT SOURCES,” attorney's docket number 30794.268-US-P1 (2008-467);

U.S. Provisional Application Ser. No. 60/051,286, filed on May 7, 2008, by Hisashi Masui, Shuji Nakamura, and Steven P. DenBaars, entitled “INTRODUCTION OF OPTICAL-POLARIZATION MAINTAINING WAVEGUIDE PLATES,” attorney's docket number 30794.269-US-P1 (2008-468);

U.S. Provisional Application Ser. No. 61/088,251, filed on Aug. 12, 2008, by Hisashi Masui, Natalie N. Fellows, Steven P. DenBaars, and Shuji Nakamura, entitled “ADVANTAGES OF USING THE (1122) PLANE OF GALLIUM NITRIDE BASED WURTZITE SEMICONDUCTORS FOR LIGHT-EMITTING DEVICES,” attorney's docket number 30794.278-US-P1 (2008-654); and

U.S. Utility application Ser. No. ______, filed on same date herewith, by Natalie N. Fellows, Hisashi Masui, Steven P. DenBaars, and Shuji Nakamura, entitled “TUNABLE WHITE LIGHT BASED ON POLARIZATION SENSITIVE LIGHT-EMITTING DIODES,” attorney's docket number 30794.277-US-U1 (2008-653-2), which application claims the benefit under 35 U.S.C. Section 119(e) of U.S. Provisional Application Ser. No. 61/086,428, filed on Aug. 5, 2008, by Natalie N. Fellows, Hisashi Masui, Steven P. DenBaars, and Shuji Nakamura, entitled “TUNABLE WHITE LIGHT BASED ON POLARIZATION SENSITIVE LIGHT-EMITTING DIODES,” attorney's docket number 30794.277-US-P1 (2008-653-1) and U.S. Provisional Application Ser. No. 61/106,035, filed on Oct. 16, 2008, by Natalie N. Fellows, Hisashi Masui, Steven P. DenBaars, and Shuji Nakamura, entitled “WHITE LIGHT-EMITTING SEMICONDUCTOR DEVICES WITH POLARIZED LIGHT EMISSION,” attorney's docket number 30794.277-US-P2 (2008-653-1);

which applications are incorporated by reference herein.

### BACKGROUND OF THE INVENTION

1. Field of the Invention

This invention relates to phosphors emitting polarized light and their use in Liquid Crystal Displays (LCDs).

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

The first twisted nematic liquid-crystal display (TN/LCD) was developed in 1967 at the Liquid Crystal Institute at Kent State University and has become the industry standard. (S. M. Allen [1] provides an overview of liquid crystals and describes how LCDs work).

FIG. 1 illustrates such a typical LCD 100, comprising a liquid crystal 102 between a first transparent electrode 104 and a second transparent electrode 106, a top polarizer 108 and a bottom polarizer 110 (the liquid crystal 102, first transparent electrode 104, and second transparent electrode 106 are between the top polarizer 108 and bottom polarizer 110), and a reflector 112 positioned behind the bottom polarizer 110 (so that the bottom polarizer 110 is between the reflector 112 and the second transparent electrode 106). It works by having two electrode surfaces 114, 116 (surfaces of the first electrode 104 and second electrode 106, respectively) providing homogeneous boundary conditions but with the two preferred orientation directions being rotated by 90° with respect to each other. In the absence of an electric field, a uniformly twisted region of nematic phase across the thickness of the device 100 is achieved. When a field is provided perpendicular to the thin liquid film 102, the dielectric anisotropy of the liquid-crystal molecules in the liquid crystal 102 causes them to turn to align with the field direction. When the field is turned off the molecules will revert back to their original state. Also shown is the unpolarized light source 118.

The image contrast from the device 100 is achieved by reflective light by utilizing an optical polarizer 108, 110 near the surface 120, 122 of both electrodes 104, 106. The bottom substrate is mirrored 112 on the underside for high reflectivity. Light 118 that is unpolarized enters through the top of the device and is polarized parallel to the upper orientation direction of the top polarizer 108. If the electrode 104 is in the “off” state then the light proceeds through the device 100 and the polarization follows the orientation of the liquid-crystal molecules in the liquid crystal 102 as they twist through 90°. Next, the light passes through the bottom polarizer 110 to the reflecting surface 112, bounces back through the bottom polarizer 110, reverses orientation again through the liquid-crystal molecules in the liquid crystal 102 and passes through unhindered by the top polarizer 108. This “off” state therefore appears bright to the viewer since they are seeing the ambient light that first entered the device 100. For the “on” state the light again enters the top polarizer 108 but now the electrodes 104, 106 are activated and the liquid-crystal molecules in the crystal 102 are aligned normal to the substrate (or normal to the reflector 112). Therefore, no rotation of the polarization direction occurs so no light passes through to the bottom polarizer 110 to be reflected back to the viewer. In this case the “on” state appears dark to the observer. This “off” and “on” state gives excellent image contrast for the display 100.

FIG. 2 illustrates that backlighting technology (e.g., a color, backlight liquid crystal display 124) is now a more compact application for current LCDs. The reflector 112 normally used in LCDs 100 is now replaced with a light source 126 (unpolarized backlight). Light from this light source 126 now hits the bottom polarizer 110 first and goes through the same transitions as a non-backlighted LCD 100. For a color display 124, the color filters 128 are placed typically behind the topmost polarizer 108 and between the top polarizer 108 and the first transparent electrode 104 (FIG. 2).

What is needed in the art, however, are improved methods and apparatus for using LCDs. The present invention satisfies this need.

### SUMMARY OF THE INVENTION

To overcome the limitations in the prior art described above, and to overcome other limitations that will become apparent upon reading and understanding the present specification, the present invention utilizes an optically polarized light source in conjunction with phosphors (single crystal, polycrystalline, polymorphism, polyamorphism, amorphous, etc.), which also exhibit optical polarization, for use in LCDs and backlighting applications.

The use of polarized phosphors in the display will eliminate the need for color filters which decrease the efficiency of the LCD due to the decrease in usable light. Since a polarized light source (such as semipolar or nonpolar (Ga, Al, In, B)N) can be used, the need for two polarizers is reduced to one, thereby further improving the efficiency of the present invention's system.

Although the results were performed on YAG:Ce, the present invention is equally applicable to Y₃(Al, Ga)₅O₁₂:(Tb, Gd, Eu, Er and other rare earth ions) as well as other red, green, and blue emitting phosphors which show polarization anisotropy when excited. The term phosphor used herein refers to a material that exhibits photoluminescence which is the process of a substance absorbing a photon and then re-radiating the photon at a lower energy. Quantum mechanically, it is the process where an electron is excited to a higher energy state and then returns to the lower energy state accompanied by the emission of a photon. When using a phosphor with polarization properties for LCD backlighting applications, a system to selectively pick which polarization state is needed without the extra polarizer is enabled, thereby making the system more compact and efficient.

In one embodiment, the present invention describes an apparatus for displaying images, comprising: (a) a light source for emitting a primary light having a specified polarization direction and comprising one or more first wavelengths; (b) a luminescent material, optically pumped by the primary light, for emitting a secondary light having a same or similar polarization direction to the polarization direction of the primary light and comprising one or more second wavelengths that are different from the first wavelengths; and (c) a liquid crystal for receiving the secondary light and primary light, and for displaying one or more images in response thereto; (d) wherein the luminescent material is positioned between the light source and the liquid crystal.

The primary light emitted by the light source is a linearly polarized light that may minimize usage of a polarizer. The light source may comprise one or more nonpolar or semipolar III-nitride based Light Emitting Devices, such as Light Emitting Diodes (LEDs) and/or Laser Diodes (LDs). The primary and secondary light may comprise at least some visible light to minimize usage of a color filter.

The present invention further discloses a luminescent material, e.g, one or more phosphors, having a structure that emits polarized light when optically pumped by primary light from a polarized light source having a polarization ratio. The structure is typically crystalline, however, the luminescent material may have any structure that emits the polarized light having the same value polarization ratio as the primary light, e.g., a polarization ratio value between 0 and 1.

### BRIEF DESCRIPTION OF THE DRAWINGS

Referring now to the drawings in which like reference numbers represent corresponding parts throughout:

FIG. 1 is an illustration of a typical LCD.

FIG. 2 is an illustration of a typical color, backlight LCD (i.e. the LCD is illuminated from the back by a backlight).

FIG. 3 illustrates polarization orientation and optical polarization states of light through a backlight LCD.

FIG. 4 is a schematic of the present invention.

FIG. 5 illustrates polarization orientation and optical polarization states for the present invention.

FIG. 6 illustrates experimental results for polarization of emission from a YAG:Ce³⁺ single crystal, plotting intensity, in arbitrary units (arb. units), of the emission of the excitation source (450 nm c-plane LED) and emission of the YAG:Ce³⁺ single crystal (YAG crystal) passing through a polarizer as a function of polarizer angle, showing polarization of the excitation source (c-plane LED emitting 450 nm wavelength light) and polarized emission of the YAG crystal (yellow light), wherein the YAG:Ce³⁺ single crystal is optically pumped by the excitation source to produce the yellow emission, the polarizer angle is the angle between the polarizing axis of the polarizer and the <100> direction of the YAG crystal, substantially all of the light incident on the polarizer is transmitted through the polarizer when the incident light's polarization is parallel with the polarizing axis, and the polarizer angle is varied between 0 and 180 degrees (deg).

FIG. 7 illustrates experimental results for a YAG:Ce³⁺ powder (depolarization of emission from the YAG phosphor powder as compared to the optical pump polarization), plotting intensity of the emission of the excitation source and emission of the YAG:Ce³⁺ powder (depolarized phosphor powder) passing through the polarizer as a function of polarizer angle, showing polarization of the excitation source (c-plane LED emitting 450 nm wavelength light) and depolarized emission from the phosphor powder (yellow light), wherein the YAG:Ce³⁺ powder is optically pumped by the excitation source to produce the yellow emission, the polarizer angle is the angle between the polarizing axis of the polarizer and a randomly selected starting position of the polarizer, substantially all of the light incident on the polarizer is transmitted through the polarizer when the incident light's polarization is parallel with the polarizing axis, and the polarizer angle is varied between 0 and 180 degrees (deg).

FIG. 8(a) is a cross-sectional schematic of a light-emitting device for emitting polarized light, according to an embodiment of the present invention.

FIG. 8(b) is a cross-sectional schematic of a light emitting active layer of the light-emitting device for emitting polarized light, according to an embodiment of the present invention.

FIG. 9 is a flowchart illustrating a method of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The inventors performed an experiment showing that phosphor powder was only very slightly polarized. However, the inventors also performed an experiment showing the down-converted emission of a cubic single crystal (YAG:Ce³⁺) was 100% polarized when excited by linearly polarized light, illustrating that single crystal phosphors are beneficial in LCDs. Consequently, a single crystal phosphor can be used to fabricate an efficient LCD that eliminates one polarizer and color filters and utilizes the polarizing nature of the phosphor in conjunction with a polarizing source such as a semipolar or nonpolar (Ga, Al, In, B)N LED.

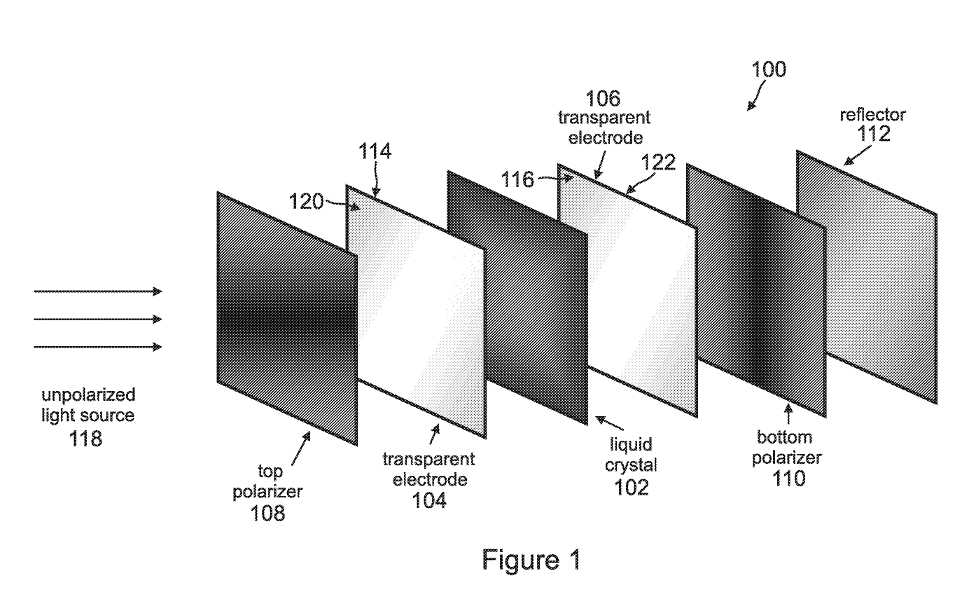

As described above in reference to FIG. 1, LCDs 100 typically contain a thin layer of liquid crystals 102 sandwiched between two substrates with conducting electrodes 104, 106. One of the electrodes 104, 106 must be transparent, and both should have some type of surface 114, 116 treatment to affect the initial state of the liquid-crystals 102 at the surface 114, 116 of the substrates. A top polarizer 108 allows for the light to enter polarized, and the bottom polarizer 110 allows for light to be reflected back to the viewer (electrically “off” state) or extinguishes the light so no light is reflected back to the viewer (electrically “on” state). Color filters 128 can then be added to allow for color display.

The present invention increases the efficiency of LCDs by lowering their power consumption and energy usage by employing a polarizing phosphor sheet in conjunction with the LCD devices. The backlighting of an LCD is normally produced by a source 126 which needs to be linearly polarized by a polarizer. In the present invention, the phosphor sheet is polarized from a linearly polarized source such as a semipolar or nonpolar (Ga, Al, In, B)N LED, thereby eliminating the need for the top polarizer 108 used in an LCD unit 124.

Nomenclature

The term “(Al,Ga,In)N” or III-nitride as used herein is intended to be broadly construed to include respective nitrides of the single species, Al, Ga, and In, as well as binary, ternary and quaternary compositions of such Group III metal species. Accordingly, the term (Al, Ga, In)N comprehends the compounds AlN, GaN, and InN, as well as the ternary compounds AlGaN, GaInN, and AlInN, and the quaternary compound AlGaInN, as species included in such nomenclature. When two or more of the (Ga, Al, In) component species are present, all possible compositions, including stoichiometric proportions as well as “off-stoichiometric” proportions (with respect to the relative mole fractions present of each of the (Ga, Al, In) component species that are present in the composition), can be employed within the broad scope of the invention. Accordingly, it will be appreciated that the discussion of the invention hereinafter in reference to GaN materials is applicable to the formation of various other (Al, Ga, In)N material species. Further, (Al,Ga,In)N materials within the scope of the invention may further include minor quantities of dopants and/or other impurity or inclusional materials.

Technical Description

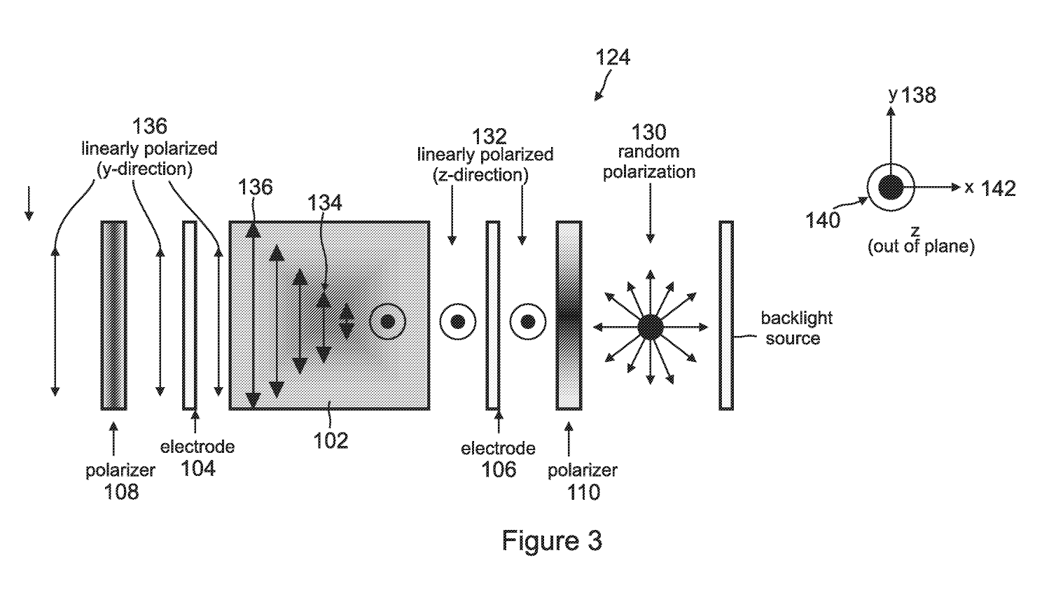

In order for an LCD 124 to work, it needs to have polarized light emission as its source. In a backlight LCD 124, light emitted from the light source 126 begins in a state of random polarization. FIG. 3 shows the different states of polarization that the light goes through as it passes through an LCD 124. The random polarization state or randomly polarized light 130 must first go through a polarizer 110 that selects one linear state of polarization 132 (e.g., linearly polarized in the z direction). This polarizer 110 is absolutely necessary in LCDs 124 currently on the market since only linearly polarized 132 light will be affected by the liquid-crystals 102. The liquid crystal 102 can then rotate 134 the polarization 132 of the linearly polarized light, to form light linearly polarized 136 in another direction (e.g., y direction) (“off state”, thereby allowing the light having rotated polarization 136 to pass through the top polarizer 108), or the liquid crystal 102 can maintain the polarization state 132 (“on state”). However, if the light enters the liquid-crystal 102 unpolarized the random polarization states 130 are affected but the randomization is averaged out and the result is no net polarization and therefore no image contrast is possible for the LCD 124. The arrow 138 represents the y direction (direction of the light linearly polarized 136 in the y-direction), the circle and dot 140 represents the z-direction (perpendicular to, or out of, the plane of the paper, and also the direction of the light linearly polarized 132 in the z-direction), and the arrow 142 represents the x direction.

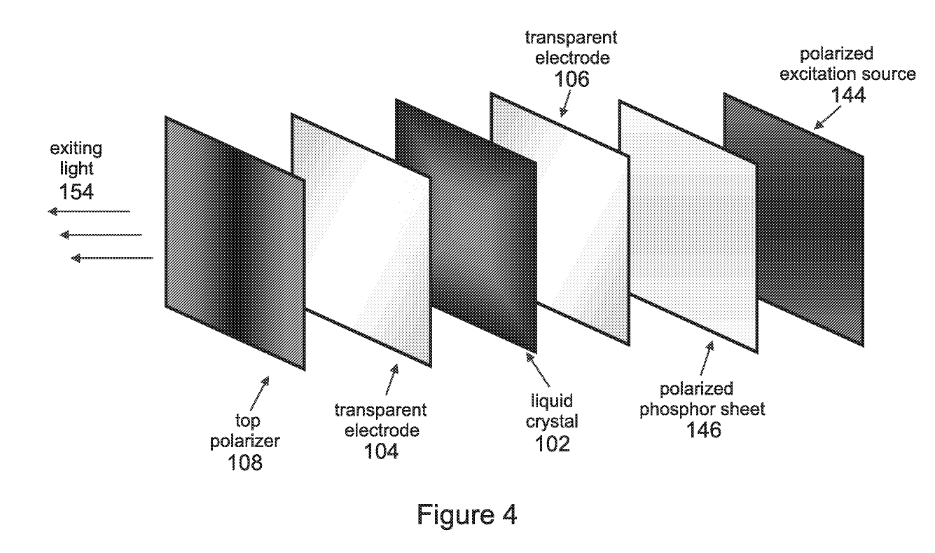

As shown in FIG. 4, the present invention eliminates this first (bottom) polarizer 110 by utilizing a polarizing source 144 (e.g., polarized excitation source) such as a semipolar or nonpolar Ga(In, Al, B)N LED that has been shown to have a high degree of optical polarization anisotropy. Next, the present invention employs a phosphor screen 146 (e.g., polarized phosphor sheet) that is also polarization sensitive (FIG. 4).

This is a non-obvious usage of phosphors since the most common phosphor used to achieve solid state white lighting, and the phosphor (used in the phosphor screen 146) which led to the present invention, Y₃Al₅O₁₂:Ce³⁺ (YAG hereafter), takes on a cubic form. Cubic crystals by symmetry should have no preferential polarization state when excited by polarized light emission. The excitation source (in this case, a nonpolar GaN LED) should show optical polarization anisotropy but the excited luminescence emission of the YAG phosphor should be unpolarized. However, it is believed that when Ce is substituted on a Y site, the crystal becomes quasi-cubic and optical polarization can be achieved. (P. P Feofilov [2] discusses this phenomenon for cubic crystals but only speculates on the phenomenon for phosphors.) This phenomenon is exploited in the present invention in order to maintain polarization in a LCD.

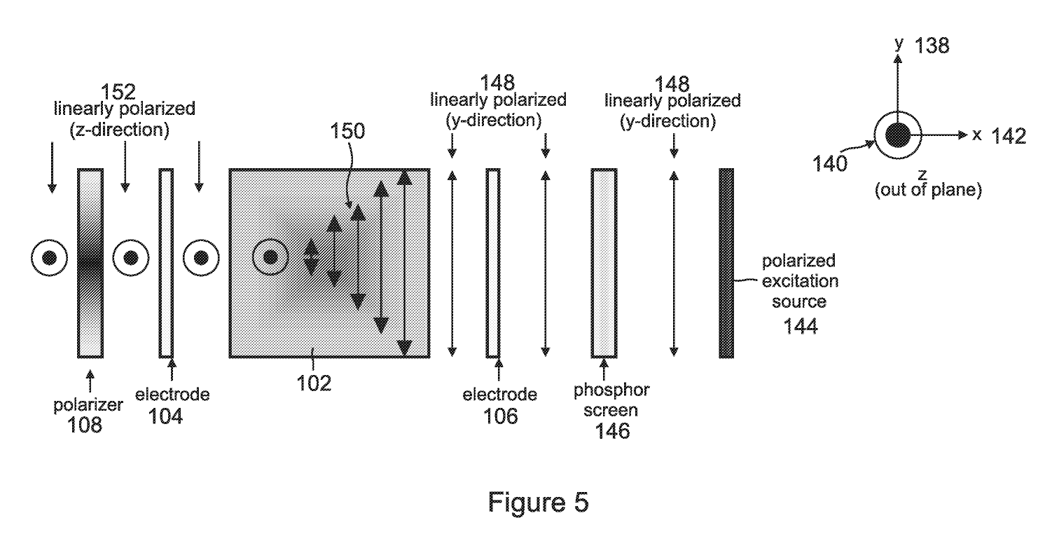

The polarization orientation for the present invention is shown in FIG. 5. Linearly polarized light (e.g., linearly polarized 148 in the y-direction), from the polarized excitation source 144, is used as a backlight source. Next, this polarized light passes through the phosphor screen 146 which allows both the polarized backlight source's light to pass through (still polarized 148) as well as the phosphor's 146 emission spectrum, which is also (e.g., linearly) polarized 148 in the same direction as the light from the polarized excitation source (e.g. in the y direction). Since both these spectra are polarized linearly in the same state 148 they can pass through the liquid-crystal 102 and can be manipulated as is done in normal LCDs. The polarized light can both be rotated 150 to form light linearly polarized in another direction 152, e.g., the z direction, (i.e., the light from the excitation source 144 and the phosphor's 146 emission are both linearly polarized 152 in the z direction) and allowed to pass through the top polarizer 108 (“off” state) as exiting light 154 (see FIG. 4), or it can maintain its polarization state 148 so that the top polarizer 108 blocks it (“on” state). In FIG. 5, arrow 138 represents the y direction (direction of the light linearly polarized 148 in the y-direction), the circle and dot 140 represents the z-direction (perpendicular to, or out of, the plane of the paper, and the direction of the light linearly polarized 152 in the z-direction), and the arrow 142 represents the x direction.

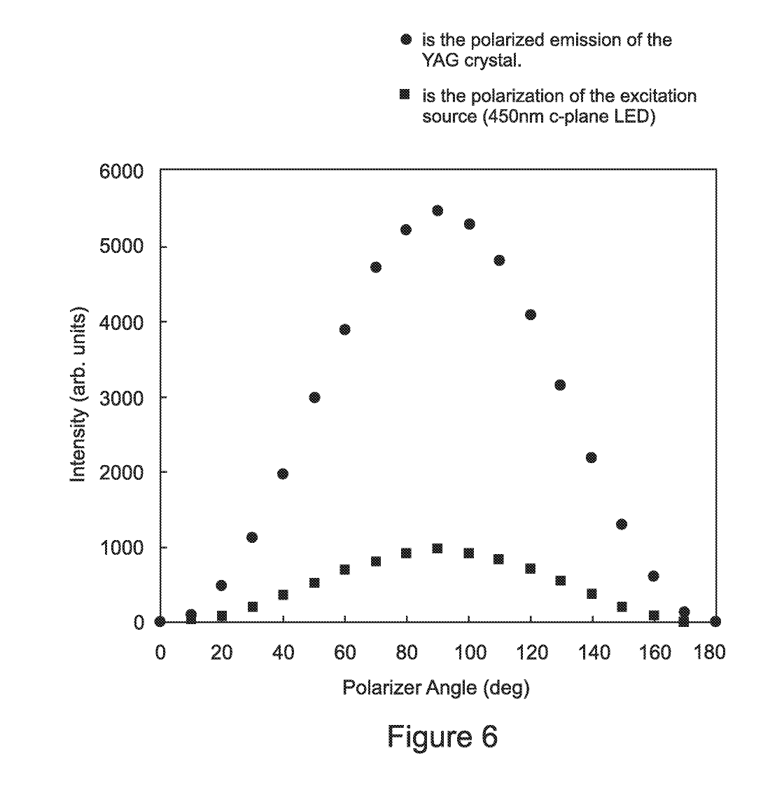

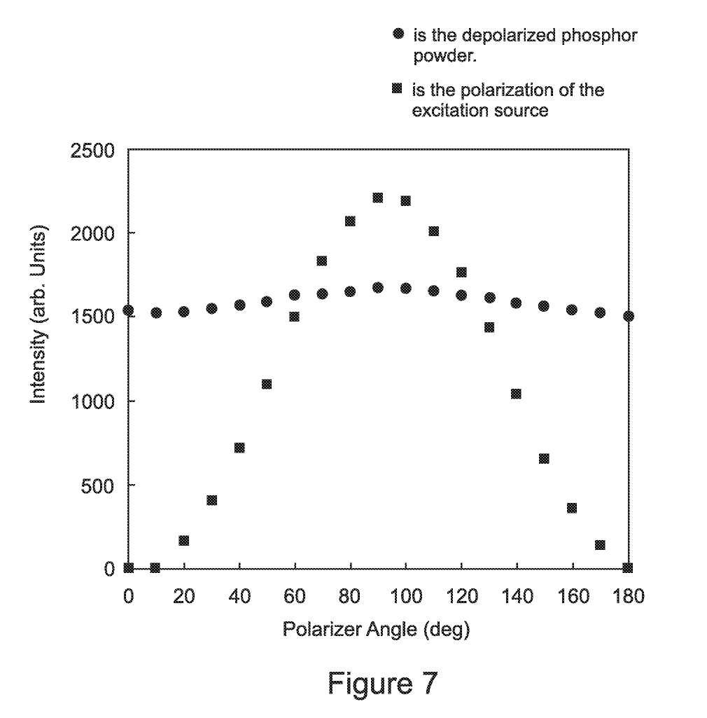

An experiment was performed with a single crystal YAG:Ce³⁺, which showed that the phosphor's 146 emission is, in fact, linearly polarized when excited with linear polarized light. FIG. 6 illustrates the optical polarization of YAG:Ce³⁺ single crystal that can be used in the screen 146, wherein the polarization of the excitation source 144 and the polarized emission of the YAG crystal is shown. This polarizing phosphor has gone unnoticed, most likely due to the state in which the phosphor is used. For white LEDs, phosphor powders are used, are dispersed in some type of resin, and then are placed directly onto the LED die. This scattering of the phosphor powders causes depolarization of the emitted light (FIG. 7). Specifically, FIG. 7 illustrates depolarization of a YAG phosphor powder, wherein the polarization of the excitation source (“blue”), as compared to the transmission of the depolarized phosphor powder (“yellow”), is shown.

FIG. 6 illustrates how a luminescent material having a crystalline structure (in this case a single crystal phosphor) emits polarized light (secondary light that is yellow) when optically pumped by a polarized light source. Specifically, FIG. 6 is a graph demonstrating the sin² θ(or cos² θ) intensity dependence of the YAG single crystal emission, when excited with polarized light. The polarization ratio, ×, defined as (I_{⊥}−I_{∥})/(I_{⊥}+I_{∥}) was 1 for both the excitation source and the YAG single crystal, whereas × was 1 and 0.054 for the excitation source and phosphor powder respectively (where I_{⊥} is the intensity of light having a polarization component perpendicular to the polarizer's polarizing axis and I_{∥} is the intensity of light having a polarization parallel to the polarizer's polarizing axis). The dependence of FIG. 6 is the signature for polarized light emission. This experiment led to the present invention and is the key to the present invention's design.

Note that in the case of the phosphor powder (FIG. 7) there is no directionality because the phosphors are a random conglomeration of particles. Because the phosphors were put on to a square glass slide, a right-handed co-ordinate system could be assigned to the phosphors. The starting position of the polarizer was randomly selected and the polarizer was rotated 180 degrees with respect to the randomly selected starting position.

Thus, FIG. 4, FIG. 5, and FIG. 6 illustrate an apparatus for displaying images, comprising a light source 144 for emitting a primary light having a specified polarization direction 148 and comprising one or more first wavelengths; a luminescent material 146 (comprising, but not limited to, one or more phosphors, for example), optically pumped by the primary light, for emitting a secondary light having a similar polarization direction 148 to the polarization direction of the primary light and comprising one or more second wavelengths that are different from the first wavelengths; and a liquid crystal 102 for receiving the secondary light and the primary light, for displaying one or more images in response thereto; wherein the luminescent material 146 is positioned between the light source 144 and the liquid crystal 102. Because the primary light emitted by the light source 144 is a linearly polarized light, the light source 144 minimizes the usage, if desired, of a polarizer such as 110 (e.g., less polarizer can be used, or the polarizer 110 can be eliminated).

Polarized Light Source

Although FIG. 6 illustrates the use of a c-plane GaN LED, the light source 144 may also comprise one or more nonpolar or semipolar III-nitride based Light Emitting Devices, such as LEDs or LDs, for example.

In order to get polarized light out of a c-plane LED, the light must be emitted from sidewalls of the c-plane LED (i.e., light emitted from the sidewalls of the c-plane GaN LED is polarized, e.g., linearly polarized).

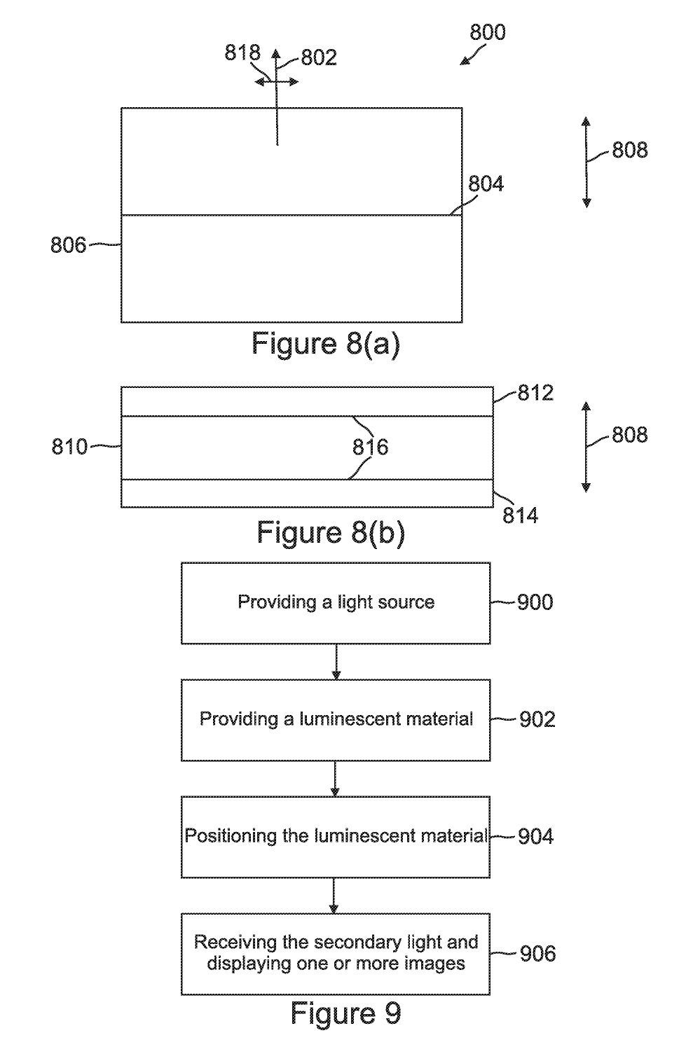

FIG. 8(a) illustrates an LED 800 that emits polarized light 802. The LED 800 is nonpolar or semipolar and comprises III-nitride based materials, and is on a crystallographic plane 804 of a wurtzite III-nitride based substrate 806 (or wurtzite III-nitride based hetero-epitaxial template). If the crystallographic plane 804 is a nonpolar plane (e.g., a-plane or m-plane), the LED 800 is nonpolar. If the crystallographic plane 804 is a plane other than the c, m, and a plane of a wurtzite III-nitride based substrate or hetero-epitaxial template 806, the light emitting device 800 is semipolar. Also shown is the orientation 808 of the III-nitride based material, wherein the arrow 808 indicates the nonpolar axis (e.g., m-axis or a-axis) direction of the III-nitride in the case of a nonpolar LED 800, and any other axis (other than a c-axis) in the case of a semipolar LED 800.

FIG. 8(b) illustrates the LED 800 typically further comprises a III-nitride light emitting active region 810 (typically an indium containing quantum well, such as, but not limited to InGaN) between barrier layers 812, 814 (e.g. GaN). The layers 810, 812, 814 are typically between a III-nitride n-type layer and a III-nitride p-type layer that are also on the substrate 806. The semipolar or nonpolar LED's 800 light emitting active layer 810 experiences reduced polarization induced fields and a reduced quantum confined stark effect, as compared to a polar light emitting active layer in a polar light emitting device grown along a c-axis of III-nitride. The polarization induced fields are reduced at interfaces 816 with the active layer 810, wherein the interfaces 816 are semipolar or nonpolar planes of III-nitride.

The polarized light 802 emitted by the active layer 810 has a linear polarization 818 and a polarization ratio.

Method of Fabrication

FIG. 9 is a flowchart illustrating a method of fabricating an apparatus for displaying images. The method comprises the following steps:

Block 900 represents providing a light source, such as a polarized light source 800, for example. The light source is capable of emitting a primary light having a specified polarization direction and polarization ratio and comprising one or more first wavelengths.

Block 902 represents providing a luminescent material, e.g., but not limited to, one or more phosphors, having a structure that emits polarized light when optically pumped by the primary light from the polarized light source. The structure is typically crystalline, however, the luminescent material may have any structure that emits the polarized light having the same or similar polarization ratio as the primary light, e.g., a value of polarization ratio between 0 and 1.

From experiments it appears that whatever the polarization of the source is, the luminescent material will maintain that polarization ratio. In one embodiment, the particular structure of the phosphor that maintains polarization is a phosphor that has the d to f orbital transition like YAG:Ce has. The state of polarization is maintained in that transition. There are several phosphors that have this transition so it is expected those phosphors also have the polarization ability that YAG:Ce has.

Block 904 represents positioning the luminescent material between the light source and a liquid crystal. When the luminescent material is optically pumped by the primary light, the luminescent material emits a secondary light having a polarization direction similar to that of the primary light. The secondary light is comprised one or more second wavelengths that are different from the first wavelengths.

Block 906 represents the liquid crystal receiving the secondary light (and the primary light) and displaying one or more images in response thereto. The secondary light and primary light may comprise at least some visible light to minimize usage of a color filter. Not only may color filter use be reduced, it may be eliminated.

Possible Modifications

The present invention can be used in a number of display applications. Major LCD applications include television screens, digital still cameras, mobile phones, Personal Digital Assistants (PDAs) and mobile notebook Personal Computers (PCs), to name a few.

The present invention's LCD module is new and innovative since it is comprised of a polarizing LED source and a polarizable phosphor screen. Other modifications to the present invention's unit could include, but are not limited to, various light sources that are polarized without the need for a polarizing element, and different materials that are phosphor like and that are polarization sensitive when excited by polarized light. Although the present invention has shown that single crystal phosphors are the top performers, other luminescent materials should be considered as well. Any color phosphor may be used, for example, but not limited to red, green and blue phosphors that emit red, green and blue light respectively. The use of colored phosphors may, if desired, eliminate or minimize any need for a color filter 128 in LCD applications.

Advantages and Improvements

The present invention is an improvement on existing LCDs since light-emitting devices can be used that have low power consumption as well as a small footprint. Although some LEDs can be currently used as an LCD backlight, LEDs that show optical polarization anisotropy are not currently used. When such LEDs with optical polarization are used in conjunction with a polarizable phosphor sheet, the bottom polarizer of the system is eliminated. When it is required to polarize a light source (which is the key feature necessary for LCDs), up to half of the usable light is extinguished in each polarizer used. The present invention eliminates the polarizer used to polarize the light source and allows for both white backlighting as well as color displays.

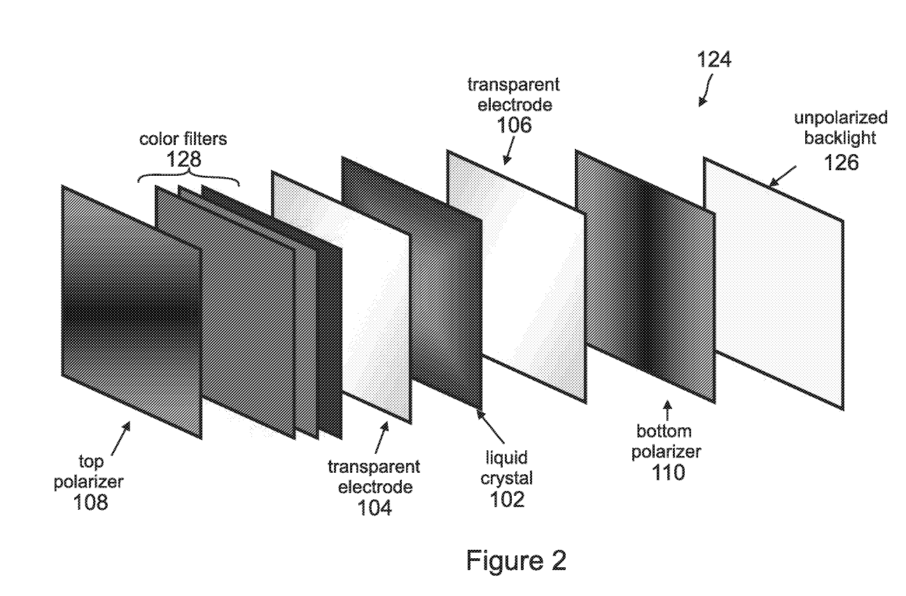

The present invention is advantageous over commercial color displays since most color displays must use color filters that are placed right before the top filter (see FIG. 2). Once the polarized light passes through the liquid-crystal and the appropriate polarization has been selected, this polarized light must then go through color filters that block all but a narrow emission band. Here, again, there are huge losses associated with LCDs using color filters. Although phosphors are not 100% efficient, they have much higher efficiency than color filters, and the amount of usable light is increased which can result in higher contrast ratios for the color displays.

The present invention increases the efficiency of the LCD since the same amount of power supplied to the LCD will produce twice the amount of usable photons. Where commercial LCDs currently utilize two polarizers and color filters that extinguish most of the source's light, the present invention eliminates one polarizer thereby gaining at least a 50% increase in efficiency. Therefore, the amount of power supplied to the system can be lowered since the source doesn't need to emit as much light as current LCDs employ. The reduction in power consumption lowers the energy needed, thereby lowering the cost and increasing the lifetime of the product. The present invention also allows for development of smaller units since the light source can be made smaller and the phosphor screens can be made very thin.

### REFERENCES

The following references are incorporated by reference herein.

[1] S. M. Allen and E. L. Thomas, The Structure of Materials, (John Wiley & Sons, Inc., New York, 1999). This book provides an overview of liquid crystals and describes how LCDs work.

[2] P. P. Feofilov, The Physical Basis of Polarized Emission, (Consultants Bureau, New York, 1961). Chapter 5 covers the polarized radiation of optically anisotropic crystals and cubic crystals.

[3] J. Gracia et. al. J. Lumin. 128, 1248 (2008).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An apparatus for displaying images, comprising:
(a) a light source for emitting a primary light having a specified polarization direction and comprising one or more first wavelengths;
(b) a luminescent material, optically pumped by the primary light, for emitting a secondary light having a similar polarization direction to the polarization direction of the primary light and comprising one or more second wavelengths that are different from the first wavelengths; and
(c) a liquid crystal for receiving the secondary light and the primary light and for displaying one or more images in response thereto;
(d) wherein the luminescent material is positioned between the light source and the liquid crystal.

2. The apparatus of claim 1, wherein the luminescent material is a single crystal phosphor.

3. The apparatus of claim 1, wherein the secondary light and the primary light include at least a visible light to minimize usage of a color filter.

4. The apparatus of claim 1, wherein the primary light emitted by the light source is a linearly polarized light that minimizes usage of a polarizer.

5. The apparatus of claim 1, wherein the light source is a nonpolar or semipolar III-nitride based light emitting device comprising a light emitting diode (LED) or laser diode, and the luminescent material is comprised of one or more phosphors.

6. A method of fabricating an apparatus for displaying images, comprising:
(a) positioning a luminescent material between a light source and a liquid crystal;
(b) wherein the light source emits a primary light having a specified polarization direction and comprising one or more first wavelengths;
(c) wherein the luminescent material is optically pumped by the primary light, the luminescent material emits a secondary light having a similar polarization direction to the polarization direction of the primary light, and the secondary light is comprised one or more second wavelengths that are different from the first wavelengths; and
(d) wherein the liquid crystal receives the secondary light and the primary light and displays one or more images in response thereto.

7. The method of claim 6, wherein the luminescent material is a single crystal phosphor.

8. The method of claim 6, wherein the secondary light and the primary light comprise at least a visible light to minimize usage of a color filter.

9. The method of claim 6, wherein the primary light emitted by the light source is a linearly polarized light that minimizes usage of a polarizer.

10. The method of claim 6, wherein the light source is a nonpolar or semipolar III-nitride based light emitting device comprising a light emitting diode (LED) or laser diode, and the luminescent material is comprised of one or more phosphors.

11. A luminescent material having a structure that emits polarized light when optically pumped by a polarized light source.

12. The luminescent material of claim 11, wherein the structure is crystalline.

13. The luminescent material of claim 11, wherein the luminescent material has the structure that emits the polarized light having a polarization ratio, the luminescent material emits the polarized light when optically pumped by primary light from the polarized light source, and the primary light has the polarization ratio.

14. The luminescent material of claim 13, wherein the value of the polarization ratio is between 0 and 1.
